(19) United States
(12) Patent Application Publication
(10) Pub. No.: US 2011/0155058 A1
(43) Pub. Date: Jun. 30, 2011

(54) SUBSTRATE PROCESSING APPARATUS HAVING A RADIANT CAVITY

(75) Inventors: David K. Carlson, San Jose, CA (US); Errol Sanchez, Tracy, CA (US); Herman Diniz, Fremont, CA (US); Satheesh Kuppurao, San Jose, CA (US)

(73) Assignee: APPLIED MATERIALS, INC., Santa Clara, CA (US)

(21) Appl. No.: 12/967,576

(22) Filed: Dec. 14, 2010

Related U.S. Application Data
(60) Provisional application No. 61/287,935, filed on Dec. 18, 2009.

(51) Int. Cl. B05C 13/02; C23C 16/00

(52) U.S. Cl. 118/722; 118/728; 118/500

(57) ABSTRACT

Methods and apparatus for processing substrates are disclosed herein. In some embodiments, an apparatus for processing a substrate may include a substrate support having a base having a convex surface, an annular ring disposed on the base, and an edge ring disposed on the annular ring to support a substrate, wherein the base, annular ring, and edge ring form a radiant cavity capable of reflecting energy radiated from a backside of a substrate when disposed on the edge ring and wherein the backside of the substrate faces the convex surface of the base. Alternatively or in combination, in some embodiments, the base may include a metal layer encapsulated between a transparent non-metal upper layer and a non-metal lower layer.

### CROSS-REFERENCE TO RELATED APPLICATIONS

This application claims benefit of U.S. provisional patent application Ser. No. 61,287,935, filed Dec. 18, 2009, which is herein incorporated by reference.

### FIELD

Embodiments of the present invention generally relate to substrate processing equipment.

### BACKGROUND

In certain substrate processes, uniform substrate processing depends upon a number of factors, including for example a heat distribution on the substrate. For example, in semiconductor deposition processes, such as epitaxial deposition, the energy provided to a substrate to be processed must be controlled such that the substrate is uniformly heated prior to, and during, the deposition process. Typically, epitaxial deposition chambers use double-sided heating to precisely control temperature uniformity of the substrate disposed therein. The combination of heating from above and below the substrate is used to try to minimize temperature variation on the surface of the substrate due to, for example, variation in the radiant energy provided from above or below the substrate.

However, double-sided heating consumes a large amount of energy, as energy is provided to both sides of the substrate. While single-sided heating of the substrate is one way to reduce energy consumption, such single-sided heating fails to provide the necessary uniform heating to the substrate as discussed above. Such non-uniform heating may lead to, for example, an epitaxial film a deposited atop the substrate surface that undesirably has a non-uniform thickness.

Thus, the present invention is disclosed herein.

### SUMMARY

Methods and apparatus for processing substrates are disclosed herein. In some embodiments, an apparatus may include a substrate support having a base having a convex surface, an annular ring disposed on the base, and an edge ring disposed on the annular ring to support a substrate, wherein the base, annular ring, and edge ring form a radiant cavity capable of reflecting energy radiated from a backside of a substrate when disposed on the edge ring and wherein the backside of the substrate faces the convex surface of the base.

In some embodiments, an apparatus may include a substrate support having a base having a metal layer encapsulated between a transparent non-metal upper layer and a non-metal lower layer, an annular ring disposed on the base, and an edge ring disposed on the annular ring to support a substrate, wherein the base, annular ring, and edge ring form a radiant cavity capable of reflecting energy radiated from a backside of a substrate when disposed on the edge ring and wherein the backside of the substrate faces the transparent non-metal upper layer of the base. Other and further embodiments of the present invention are described below.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIGS. 1A-B depict schematic cross-sectional views of process chambers in accordance with some embodiments of the present invention.

FIGS. 2A-B depict substrate supports suitable for use in a process chamber in accordance with some embodiments of the present invention.

FIG. 3 depicts a substrate support suitable for use in a process chamber in accordance with some embodiments of the present invention.

The drawings have been simplified for clarity and are not drawn to scale. To facilitate understanding, identical reference numerals have been used, wherever possible, to designate identical elements that are common to the figures. It is contemplated that some elements of one embodiment may be beneficially incorporated in other embodiments.

### DETAILED DESCRIPTION

Apparatus and methods for processing substrates are disclosed herein. In some embodiments, the apparatus includes a radiant cavity disposed adjacent to a backside of a substrate to reflect energy radiated by a substrate during exposure of the substrate to energy from an energy source. The apparatus may advantageously reduce energy consumption as well as provide more precise temperature control and uniform heating of a substrate, for example, during an epitaxial deposition process. The apparatus is also suited for other processes where uniform heating of a substrate is desired.

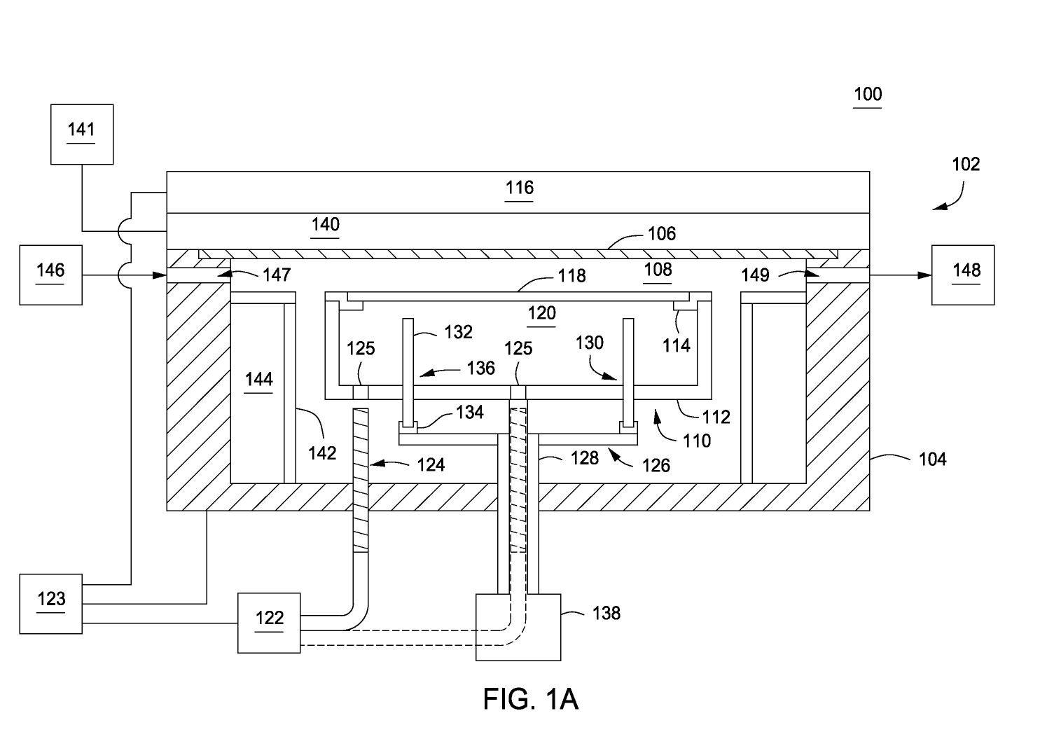

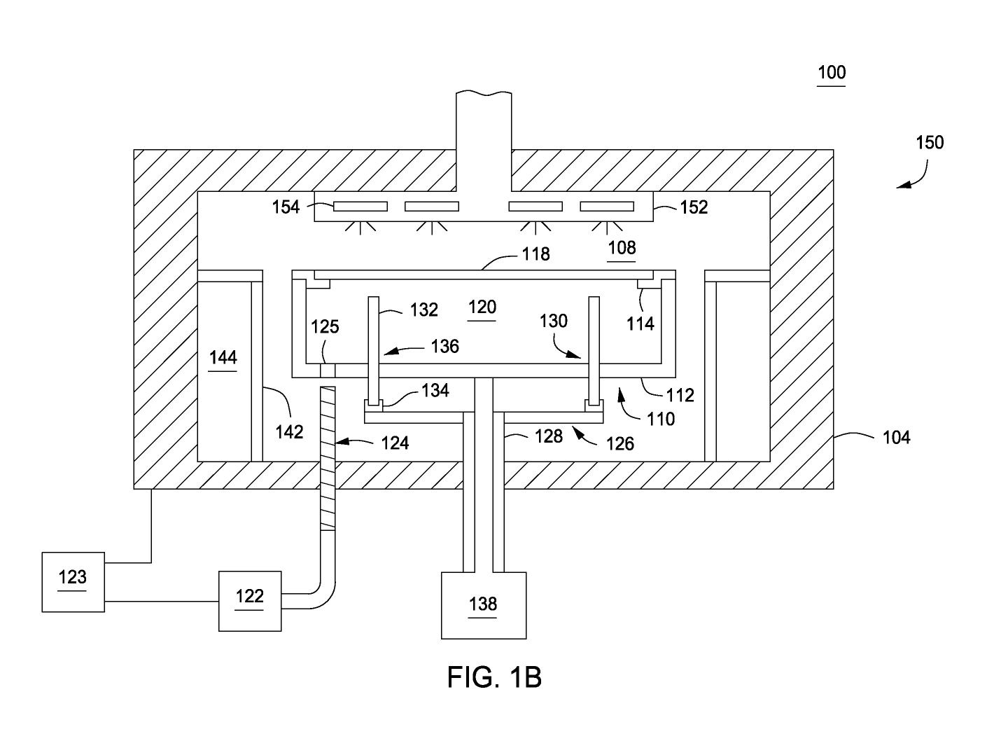

FIG. 1A depicts an apparatus 100 for processing a substrate in accordance with some embodiments of the present invention. The apparatus 100 includes a processing chamber 102 having a chamber body 104 and a transparent window 106 defining a processing volume 108. A substrate support 110 is disposed in the processing volume 108 to support a substrate 118 thereupon. The substrate support 110, together with the backside of the substrate 118, defines a cavity 120 adjacent to the backside of the substrate 118. An energy source 116 disposed above the transparent window 106 provides energy to the substrate 118 disposed on the substrate support. The substrate 118 radiates at least some of the energy from the energy source 116. Energy radiating from the backside of the substrate 118 may be reflected by walls of the cavity 120. The cavity 120 is configured to reflect the energy radiated by the substrate 118 back to the substrate 118, thereby reducing energy loss from the substrate 118. In some embodiments, a floor of the chamber body 104 may be polished (such as by electro-polishing) to enhance reflectivity and provide corrosion resistance. The floor of the chamber body 104 may be polished, for example, to a surface finish of about 10 Ra.

In some embodiments, the apparatus 100 may be configured for epitaxial deposition processes. In some embodiments, the apparatus 100 is configured for epitaxial deposition processes at temperatures between about 300 to about 900 degrees Celsius. However, the apparatus 100 is not limited to epitaxial deposition processes, and may be configured for any suitable semiconductor process requiring uniform heating of the substrate 118 during processing, and further performing such process at reduced energy consumption. Suitable processes that may benefit from the inventive apparatus may include rapid thermal processes (RTP), chemical vapor deposition (CVD), atomic layer deposition (ALD), and the like.

The substrate 118 processed in the process chamber 102 may be any suitable substrate processed in a semiconductor process chamber. The substrate 118 may be, for example, a disk-shaped, eight inch (200 mm) or twelve inch (300 mm) diameter silicon substrate; however, the substrate can comprise other suitable shapes, for example, such as square, rectangular, or the like and suited for applications such as flat panel displays or solar panels. The substrate 118 may comprise a material such as crystalline silicon (e.g., Si<100>or Si<111>), silicon oxide, strained silicon, silicon germanium, doped or undoped polysilicon, doped or undoped silicon wafers, patterned or non-patterned wafers, silicon on insulator (SOI), carbon doped silicon oxides, silicon nitride, doped silicon, germanium, gallium arsenide, glass, sapphire, or the like. In some embodiments, the substrate may be patterned, for example, having a patterned photoresist or another suitable patterned mask layer disposed thereon.

The substrate 118 is disposed atop a peripheral edge of the substrate support 110 such that the backside of the substrate is predominantly disposed over the cavity 120. In some embodiments, and as illustrated in FIG. 1A, the substrate support 110 may include a supporting member 112 and an edge ring 114. The supporting member 112 generally defines sidewalls of the cavity 120 and the edge ring 114 provides a surface for supporting the substrate 118 proximate an outer edge of the substrate 118 such that the backside of the substrate 118 is predominantly unsupported and exposed to the cavity 120. The walls of the cavity 120 reflect energy radiated from the backside of the substrate 118 during exposure to the energy source 116. The reflected energy from the walls of the cavity 120 may, for example, provide a similar benefit as would one or more lamps disposed below the substrate for heating the backside thereof. Thus, the cavity 120 may be utilized in place of one or more lamps for backside heating of a substrate.

In some embodiments, the temperature of the backside of the substrate 118 may be monitored. For example, in some embodiments a pyrometer 122 may be coupled to a temperature probe 124 positioned to measure the temperature of the backside of the substrate at a desired location (or locations). The temperature probe 124 may be coupled to the supporting member 112, for example, at the base thereof or at some other suitable location for measuring the temperature of the backside of the substrate. In some embodiments, the temperature probe may include a sapphire light pipe coupled to an optical flexible optical fiber that transmits sampled light emitted from the backside of the substrate 118 to the pyrometer 128. To facilitate an accurate temperature measurement from the backside of the substrate 118, a window, or non-reflective portion 125 of the supporting member 112, may formed from a non-metallic non-reflective material, for example, quartz. The temperature probe 124 may measure energy radiated from the backside of the substrate 118 through the non-reflective portion 125 of the supporting member 112. The pyrometer 122 may be coupled to a controller 123 which controls the power supplied to the energy source 116 in response to a measured temperature. Although depicted in FIG. 1A as measuring the temperature of the substrate 118 at a peripheral edge thereof, the temperature probe 124 may be disposed at other locations, such as proximate the central axis of the substrate support 110 (as shown by temperature probe 124 in phantom) or elsewhere. In addition, a plurality of temperature probes may be utilized to measure the temperature of multiple locations on the substrate 118. In some embodiments, a thermocouple may be used to measure a temperature proximate the location of the thermocouple. The temperature reading from the thermocouple may be correlated to the temperature of the substrate.

The temperature probe 124 may measure energy radiated from the backside of the substrate 118 continuously or periodically. For example, in embodiments where the substrate support may rotate (as discussed in more detail below) and when the temperature probe is disposed non-axially with respect to the substrate support 110, the temperature probe 124 may measure energy radiated from the backside of the substrate 118 through the non-reflective portion 125 periodically (e.g., once per revolution). In embodiments where the substrate support rotates and the temperature probe is disposed axially with respect to the substrate support 110, the temperature probe 124 may measure energy radiated from the backside of the substrate 118 continuously (although periodic measurement is also possible).

The substrate support 110 may further include a lift assembly 126 for raising and lowering the substrate 118 with respect to the edge ring 114 (or other support surface provided by the substrate support 110). In some embodiments, the substrate lift assembly 126 may include a substrate lift shaft 128 and a plurality of lift pin modules 130 selectively resting on respective pads of the substrate lift shaft 128. In some embodiments, each lift pin module 130 may include a lift pin 132 and a lift pin holder 134. The base of the lift pin 132 is supported by the lift pin holder 134 which rests on a pad of the substrate lift shaft 128. Each lift pin 132 is movably disposed through an opening 136 in the base of the supporting member 112. In operation, the substrate lift shaft 128 is moved to raise or lower the lift pins 132. The lift pins 128 may contact the backside of the substrate 118 to lift the substrate 118 off of the substrate support 110 or to lower the substrate 118 onto the substrate support 110. The lift assembly 126 and the substrate support 110 may be coupled to a lift and rotation mechanism 138 to raise and lower the lift assembly 126 and/or the substrate support 110 and/or rotate the lift assembly 126 and the substrate support 110. Alternatively, the lift and rotation mechanism 138 may comprise separate mechanisms, such as a lift mechanism to raise and lower the lift assembly 126 and/or the substrate support 110 and a rotation mechanism to rotate the lift assembly 126 and the substrate support 110 about a central axis. For example, in operation, the cavity 120 may be rotated about or translated along a central axis of the substrate support 110.

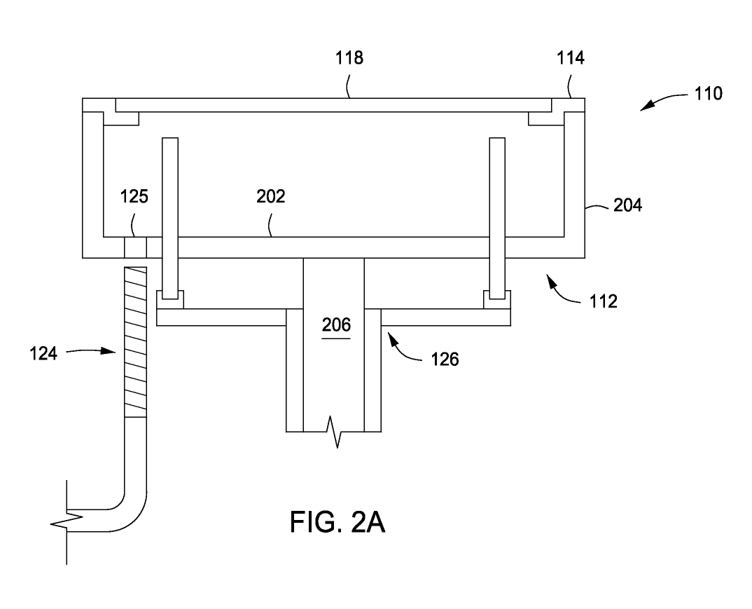

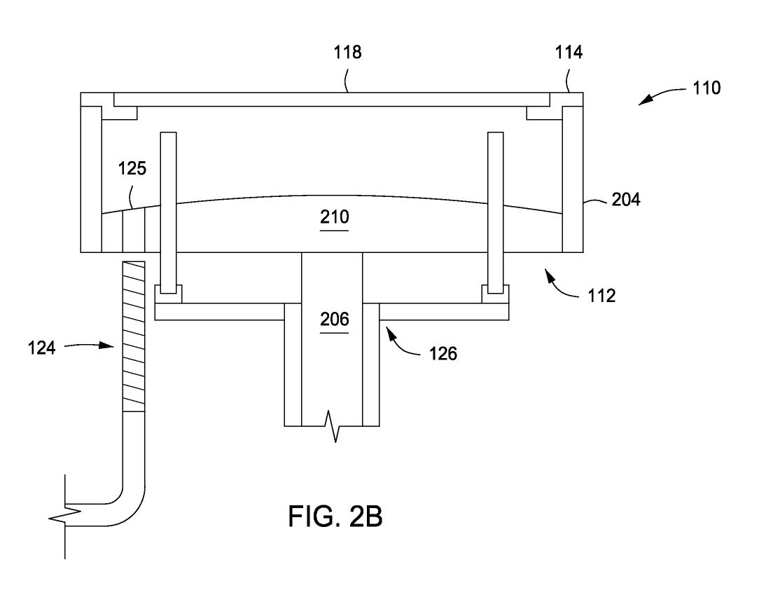

Some embodiments of the substrate support 110 are depicted in further detail in FIG. 2A. For example, the supporting member 112 may include a base 202 and an annular ring 204. The annular ring 204 may be disposed atop the base 202 or around a peripheral edge thereof (as shown). Alternatively, the base 202 and the annular ring 204 may be integrally formed. In addition, although referred to herein as a ring, the substrate support 110 may be configured with other geometries suitable for supporting substrates of varying dimensions and shapes (such as square or rectangular panels in addition to circular wafers).

The edge ring 114 may disposed atop the annular ring 204 to support an outer edge of the substrate 118. The base 202, the annular ring 204, the edge ring 114, and the backside of the substrate 118 define the cavity 120. In some embodiments, the base 202 and annular ring 204 may be fabricated from a reflective material capable of reflecting radiant energy emitted from the backside of the substrate 118. In some embodiments, the reflective material may be non-metallic, for example, for process compatibility reasons such as for epitaxial deposition processes where exposed metallic materials can corrode or cause other undesired process defects. Exemplary non-metallic materials include opaque quartz, high density opaque (HDO) quartz, or the like. In some embodiments, where process chemistry allows, the reflective material may be a metal. In some embodiments, composite structures using thin films may be used provided process wetted areas are not fabricated from process-incompatible materials. As used herein, the term “non-metallic” refers to both materials that do not include metals as well as composite materials that do not have exposed metal-containing surfaces.

The edge ring 114 may be fabricated from the same types of materials discussed above with respect to the base 202 and the annular ring 204. In some embodiments, the edge ring 114 may be fabricated from the same material as the base 202 and the annular ring 204. In some embodiments, depending upon heat transfer requirements, the edge ring may be fabricated from clear quartz, opaque quartz, or silicon carbide.

The base 202 may be disposed atop a shaft, or column 206 as depicted in FIG. 2. The column 206 may comprise a non-metallic material, for example, HDO quartz, silicon carbide, or another suitable material compatible with a desired substrate process, such as an epitaxial deposition process. The base 202 may have any suitable shape necessary to facilitate the backside heating of the substrate 118, for example, should the substrate 118 be circular, the base 202 may be circular. The base 202 may comprise a non-metallic material capable of reflecting radiant energy radiated from the backside of the substrate 118. For example, the non-metallic material may be selected based on, for example, the temperature or temperature profile required by a desired substrate process. A non-metallic material having a lower diffusivity (i.e., a higher reflectivity) may be selected if the temperature profile required the backside of the substrate 118 to be maintained at a higher temperature. A non-metallic material having a higher diffusivity (i.e., a lower reflectivity) may be selected when the temperature profile required the backside of the substrate 118 to be maintained at a lower temperature.

Alternatively or in combination, the diffusivity of the base 202 may be controlled by changing the thickness of the base. In some embodiments, as depicted in FIG. 2B, the diffusivity of the base may be controlled by changing the curvature of the base 202. As illustrated, the curvature of a cavity facing surface of the base 202 is convex. However, other configurations of the curvature are possible, for example, such as concave, an irregular curvature, or the like. By ‘irregular’ it is meant that the curvature may be any suitable curvature that is not completely convex or concave. The curvature may be adjusted, for example, at the peripheral edges of the base 210 to facilitate uniform heating at the peripheral edges of the substrate 118; or to compensate for temperature non-uniformities at the surface of the substrate 118 that may be caused, for example, by non-uniform energy supplied to the substrate 118 by the energy source 116.

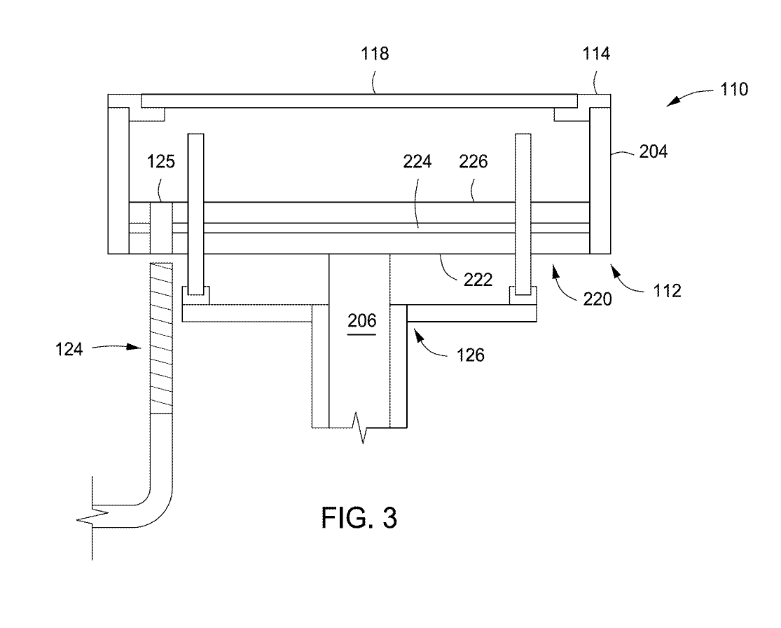

In some embodiments, the base may include a laminated structure as depicted in FIG. 3, for example, by the base 220. Here, the base 220 may include a lower layer 222, a metallic layer 224, and an upper layer 226. The metallic layer 224 may be encapsulated between the lower layer 222 and the upper layer 226 such that the metallic layer 224 is not exposed to the processing environment of the process chamber 102. For example, the metallic layer 224 may be utilized when, for example, a higher reflectivity is required (i.e., higher reflectivity than a non-metallic reflective material such as HDO quartz can provide).

The metallic layer 224 may include gold, silver, metal alloys, or other suitable metallic materials having improved reflectivity to that of the non-metallic materials discussed above. In embodiments where the metallic layer 224 is the primary reflector of radiant energy, the upper and lower layers may be fabricated from materials that are non-reflective or that have limited reflectivity, for example, clear quartz. As some reflectivity can occur at the upper layer 226, it may be desired to limit the thickness of the upper layer 226 to ensure that reflectivity primarily occurs from the metallic layer 224, or alternatively, to ensure that reflected radiant energy from the metallic layer 224 may traverse the upper layer 226 and be returned to the backside of the substrate 118. In some embodiments, the thickness of the upper layer 226 may be great enough to limit or prevent diffusion of metal atoms through the upper layer 226. In some embodiments, the upper layer 226 may have a thickness of between about 1 to about 3 mm.

The annular ring 204 may be utilized with any suitable embodiments of a base as described above and depicted in FIGS. 2A-B and 3. The annular ring 204, although depicted as an annular structure herein, may be any suitable shape as necessary to process the substrate 118. For example, the annular ring 204 may be rectangular, square, or of any suitable shape necessary to provide the cavity 120 having necessary dimensions and/or configuration to facilitate uniform backside heating of a particular substrate having a particular geometry. The annular ring 204 may comprise a non-metallic reflective material including quartz, HDO quartz, or the like. In some embodiments, the annular ring 204 is HDO quartz. In some embodiments, the diffusivity of the annular ring may be adjusted, for example, by changing the thickness of the annular ring and/or changing the curvature or geometry of the cavity facing surfaces. As discussed above regarding the base, the thickness and/or curvature may be adjusted to increase or decrease diffusivity, or to adjust the distribution of reflected radiant energy incident on the backside of the substrate 118.

In some embodiments, the annular ring 204 may comprise a non-metallic non-reflective material, for example, clear quartz. Such embodiments may include, for example, when it is desired to limit backside heating of the substrate 118, or alternatively, when the base of the supporting member 112 acts as the primary reflector of radiant energy.

In some embodiments, the annular ring 204 may include a laminated structure (not shown), for example, having a metallic layer encapsulated between an inner and outer layer of non-metallic non-reflective material. As discussed above regarding the laminated base 220, a metallic layer may be utilized when, for example, a higher reflectivity is required than a non-metallic reflective material can provide.

Returning to FIG. 1A, the energy source 116 may be any suitable energy source that may be utilized with the processes describe above, such as epitaxial deposition, RTP and the like. The energy source may include any suitable heating source, such as those emitting ultraviolet, infrared, or visible radiation, and/or those configured for RTP, epitaxial deposition, or resistive heating. As depicted in FIG. 1A, the energy source is separated from the transparent window 106 by an air space, or cooling plenum 140. The transparent window 106 may comprise any suitable non-metallic non-reflective material, for example, such as clear quartz or the like.

The cooling plenum 140 is a confined air space between the energy source 116 and the transparent window 106 that may facilitate the flow of a cooling gas such as air, nitrogen (N₂), argon (Ar), helium (He) or the like through the cooling plenum. The cooling plenum 140 may, for example, be utilized to control the temperature of the transparent window 106. For example, temperature variation in the transparent window 106 may undesirably facilitate a non-uniform flow of energy therethrough and incident upon the substrate surface. Thus, the cooling plenum 140 may be provided to limit non-uniform flow of energy through the transparent window 106 and incident upon the substrate surface. A pressure in the cooling plenum may be controlled by a pressure control mechanism 141. Precise control of the pressure in the cooling plenum 140 may prevent potential over-pressurization of the plenum 140, which could cause deflection or breakage of the transparent window 106. In addition, by improving pressure control, a thickness of the transparent window 106 may be reduced without concern of breakage of the window due to over-pressurization. The reduced thickness may facilitate reduced absorption of energy provided by the energy source 116 as the energy passes through the transparent window 106 enabling more efficient operation of the apparatus. For example, the reduced absorption by the transparent window 106 may facilitate allowing a desired quantity of energy to be provided to the front side of the substrate 118 at a reduced power of the energy source 116 as compared to an apparatus having a thicker window.

The apparatus 100 may further comprise a liner 142 lining at least portions of the processing volume 108. For example, the liner 142 may be provided along sides of the inner walls of the chamber body 104, adjacent to the substrate support 110. In some embodiments, the liner 142, or a separate liner, may also cover the floor of the chamber body 104. The liner 142 may comprise a reflective material, or a non-metallic reflective material, as discussed above, for example, such as HDO quartz, a composite reflective material, or the like. Further, as discussed above, the thickness and/or curvature of the process volume facing surface of the liner 142 may be adjusted to control the diffusivity and/or distribution of energy incident thereon, for example, from the energy source 116. In some embodiments, and as depicted in FIG. 1A, the liner 142 may be separated from the chamber body 104 by an insulating space 144. The insulating space 114 may be evacuated (i.e., a vacuum) or maintained at a desired pressure such that heat loss from the processing volume 108 is controlled. The liner 142 and cavity 120 may act in combination to facilitate control over temperature uniformity at the substrate surface.

The controller 123 generally comprises a central processing unit (CPU), a memory, and support circuits and is coupled to and controls the process chamber 102 and components thereof, directly (as shown in FIG. 1A) or, alternatively, via computers (or controllers) associated with the process chamber and/or chamber components. The controller 123 may further be utilized as a temperature controller for the energy source 116 in response to feedback from the pyrometer 122. Alternatively, separate controllers may be utilized, e.g., a first controller for controlling temperature, and a second controller for controlling the process chamber 102 and/or components thereof.

In operation, a process gas may be provided by a gas panel 146 and flowed into the processing volume by one or more gas injection ports. In the embodiment depicted in FIG. 1A, a side injection port 147 is shown. Alternatively or in combination, other injection port locations, such as a top injection port disposed in the lid of the chamber, may be utilized. The process gas may be flowed into the processing volume 108 and across the surface of the substrate 118. The flow rate of the process gas may be controlled by, for example, a pressure differential formed between the side injection port 147 and an exhaust port 149 coupled to an exhaust system 148, for example, via a turbo pump or other suitable pumping mechanism. The energy source 116 may provide energy to the substrate 118 prior to and/or during the flow of process gas into the processing volume 108. A portion of the energy provided may be reflected from the liner 142 to control the temperature in the processing volume. A portion of the energy provided may be absorbed by the substrate and subsequently radiated therefrom (e.g., from the backside of the substrate 118) into the cavity 120. The cavity 120 may reflect some or all of the radiant energy to the backside of the substrate 118, thus facilitating backside heating of the substrate 118, enhancing temperature uniformity on the substrate surface, and controlling heat loss from the substrate surface. In some embodiments, where a desired temperature of the substrate may be required before and/or during process gas flow the temperature probe 124 may be used to monitor the temperature of the backside of the substrate 118. In response to the temperature measured by the temperature probe, the controller 123 may control the energy source 116 to provide more or less energy in order to maintain a desired temperature of the substrate 118. Upon exposure to energy provided by the energy source, the process gas may react at the surface of the substrate 118, for example, forming an epitaxial layer thereon. Alternatively, if multiple process gases are utilized, the process gases may react with each other upon exposure to energy forming a gaseous product which may be deposited on the substrate surface forming, for example, a deposited layer such as by chemical vapor deposition (CVD) or atomic layer deposition (ALD). The process gas may be flowed until a desired thickness of the layer is achieved. Alternative processes may also be utilized to advantage in the inventive apparatus.

Embodiments of the substrate support 110 disclosed herein may be utilized with various configurations of a process chamber. For example, FIG. 1B depicts a process chamber 150 in accordance with some embodiments of the present invention. For example, the process chamber 150 may be similar to the process chamber 102 in some aspects, and accordingly, the same numbers may be used to illustrated elements common to both process chambers in FIGS. 1A-B. Variations of the elements shown in FIG. 1A may be applicable to the process chamber 150 described with respect to FIG. 1B, although they are omitted from FIG. 1B for clarity.

For example, the process chamber 150 can include a gas delivery inlet 152 to provide a process gas to the substrate 118 disposed on the substrate support 110. For example, the gas delivery inlet 152 may provide gas from any suitable gas source, such as a gas panel or the like. In some embodiments, the gas delivery inlet 152 may provide reactive species, for example, from a remote plasma source or the like. Alternatively, the gas delivery inlet 152 may include a cathode (not shown), for example, to produce a capacitively coupled plasma in the process chamber 150, or the process chamber 150 may further comprise inductive coils (not shown) to produce an inductively coupled plasma from a process gas flowed through the gas delivery inlet 152. The gas delivery inlet 152 may be any suitable gas delivery inlet, such as a showerhead or the like. The gas delivery inlet 152 may include an energy source 154 to provide energy to the substrate 118. For example, the energy source 154 may be one or more resistive heating elements or the like disposed in or proximate the gas delivery inlet. For example, the energy source 154 may energize (e.g., heat) a process gas flowing through the gas delivery inlet 152. The heated process gas may contact the substrate 118 and transfer heat to the substrate 118, or alternatively, radiate heat which absorbed by the substrate 118. Alternatively or in combination, the energy source may heat the gas delivery inlet 152 itself, which, in turn, may radiate heat to the substrate 118.

Thus, apparatus for processing substrates have been disclosed herein. The apparatus may advantageously reduce energy consumption as well as provide more precise temperature control and uniform heating of a substrate, for example, during an epitaxial deposition process.

While the foregoing is directed to embodiments of the present invention, other and further embodiments of the invention may be devised without departing from the basic scope thereof.

1. Apparatus for processing a substrate, comprising:
a substrate support, comprising:
a base having a convex surface;
an annular ring disposed on the base; and
an edge ring disposed on the annular ring to support a substrate, wherein the base, annular ring, and edge ring form a radiant cavity capable of reflecting energy radiated from a backside of a substrate when disposed on the edge ring and wherein the backside of the substrate faces the convex surface of the base.

2. The apparatus of claim 1, wherein the annular ring and the base are fabricated from a non-metallic reflective material comprising at least one of high density opaque quartz or a composite reflective material.

3. The apparatus of claim 1, wherein the curvature of the convex surface of the base is selected to provide a predefined pattern of radiant energy reflected from the base to the substrate.

4. The apparatus of claim 1, further comprising:
a process chamber, wherein the substrate support is disposed in the process chamber.

5. The apparatus of claim 4, wherein the process chamber further comprises:
a transparent window disposed in a ceiling of the process chamber;
an energy source disposed above the ceiling of the process to provide energy to a substrate through the transparent window when the substrate is disposed on the substrate support; and
a cooling plenum disposed between the energy source and the transparent window to cool the transparent window by flowing a cooling gas through the cooling plenum.

6. The apparatus of claim 4, wherein the process chamber further comprises:
a gas delivery inlet disposed above the substrate support.

7. The apparatus of claim 6, wherein the process chamber further comprises:
an energy source disposed in the gas delivery inlet to provide energy to a substrate when the substrate is disposed on the substrate support.

8. The apparatus of claim 4, wherein the process chamber further comprises:
a liner disposed along an interior wall of the chamber, wherein the liner comprises a reflective material to reflect radiant energy during processing.

9. The apparatus of claim 1, wherein the radiant cavity is rotatable about a central axis and translatable along the central axis.

10. Apparatus for processing a substrate, comprising:
a substrate support, comprising:
a base having a metal layer encapsulated between a transparent non-metal upper layer and a non-metal lower layer;
an annular ring disposed on the base; and
an edge ring disposed on the annular ring to support a substrate, wherein the base, annular ring, and edge ring form a radiant cavity capable of reflecting energy radiated from a backside of a substrate when disposed on the edge ring and wherein the backside of the substrate faces the transparent non-metal upper layer of the base.

11. The apparatus of claim 10, wherein the transparent non-metal upper and lower layers comprise clear quartz.

12. The apparatus of claim 10, wherein the metal layer comprises at least one of gold or silver.

13. The apparatus of claim 10, wherein the annular ring is fabricated from a non-metallic reflective material comprising at least one of high density opaque quartz or a composite reflective material.

14. The apparatus of claim 10, further comprising:
a process chamber, wherein the substrate support is disposed in the process chamber.

15. The apparatus of claim 14, wherein the process chamber further comprises:
a transparent window disposed in a ceiling of the process chamber;
an energy source disposed above the ceiling of the process to provide energy to a substrate through the transparent window when the substrate is disposed on the substrate support; and
a cooling plenum disposed between the energy source and the transparent window to cool the transparent window by flowing a cooling gas through the cooling plenum.

16. The apparatus of claim 14, wherein the process chamber further comprises:
a gas delivery inlet disposed above the substrate support.

17. The apparatus of claim 16, wherein the process chamber further comprises:
an energy source disposed in the gas delivery inlet to provide energy to a substrate when the substrate is disposed on the substrate support.

18. The apparatus of claim 14, wherein the process chamber further comprises:
a liner disposed along an interior wall of the chamber, wherein the liner comprises a reflective material to reflect radiant energy during processing.

19. The apparatus of claim 10, wherein the radiant cavity is rotatable about a central axis and translatable along the central axis.
